(19) United States
(12) Patent Application Publication
(10) Pub. No.: US 2012/0112031 A1
(43) Pub. Date: May 10, 2012

(54) PORTABLE ELECTRONIC DEVICE CASE ACCESSORY WITH CAMERA PROTECTION

(75) Inventors: Todd Gormick, San Clemente, CA (US); Mark Thoni, Rancho Santa Margarita, CA (US)

(73) Assignee: TARGUS GROUP INTERNATIONAL, INC., Anaheim, CA (US)

(21) Appl. No.: 13/285,565

(22) Filed: Oct. 31, 2011

Related U.S. Application Data
(60) Provisional application No. 61/410,617, filed on Nov. 5, 2010.

(51) Int. Cl. H05K 7/00; B65D 85/00

(52) U.S. Cl. 248/371; 206/320

(57) ABSTRACT

Case accessories including protection covers for portable electronic devices having image capturing systems are disclosed. In some embodiments, the case may include a holder configured to secure the portable electronic device and a selectively positionable protection cover configured to protect the integrated image capturing system. In certain embodiments, the selectively positionable protection cover may be positioned using a hinged mechanism, a sliding mechanism, or a rotational mechanism.

### RELATED APPLICATIONS

This application claims priority under 35 U.S.C. §119(e) to U.S. Provisional Patent Application No. 61/410,617, filed Nov. 5, 2010, and entitled “PORTABLE ELECTRONIC DEVICE CASE ACCESSORY WITH CAMERA PROTECTION,” which is hereby incorporated by reference in its entirety.

### TECHNICAL FIELD

The present disclosure relates generally to portable electronic devices and, more specifically, to a case accessory for a portable electronic device that includes a camera protection system.

### BRIEF DESCRIPTION OF THE DRAWINGS

The written disclosure herein describes illustrative embodiments that are non-limiting and non-exhaustive. Reference is made to certain of such illustrative embodiments that are depicted in the figures, in which:

FIG. 1A illustrates a back view of an accessory for a portable electronic device that includes a hinged camera protection cover in an open position consistent with embodiments of the present disclosure.

FIG. 1B illustrates a back view of an accessory for a portable electronic device that includes a hinged camera protection cover in a closed position consistent with embodiments of the present disclosure.

FIG. 2A illustrates a front view of an accessory for a portable electronic device that includes a hinged camera protection cover in an open position consistent with embodiments of the present disclosure.

FIG. 2B illustrates a front view of an accessory for a portable electronic device that includes a hinged camera protection cover in a closed position consistent with embodiments of the present disclosure.

FIG. 3A illustrates a back view of an accessory for a portable electronic device that includes a rotating camera protection cover in an open position consistent with embodiments of the present disclosure.

FIG. 3B illustrates a back view of an accessory for a portable electronic device that includes a rotating camera protection cover in a closed position consistent with embodiments of the present disclosure.

FIG. 4A illustrates a back view of an accessory for a portable electronic device that includes a sliding camera protection cover in an open position consistent with embodiments of the present disclosure.

FIG. 4B illustrates a back view of an accessory for a portable electronic device that includes a sliding camera protection cover in a closed position consistent with embodiments of the present disclosure.

FIG. 5 illustrates a side elevation view of an embodiment of a stand case for a portable electronic device that includes hinged camera protection covers in open positions consistent with embodiments of the present disclosure.

### DETAILED DESCRIPTION

The proliferation of portable electronic devices (PEDs), including notebook and tablet computers (e.g., the Apple® iPad™), portable digital assistants (PDAs), and smartphones, has placed more computing power into the hands of users than the computing power of early computers that occupied an entire room. This portable computing power has enhanced both personal and business mobile productivity. With their increasing computing power, PEDs now often include image capturing systems (e.g., cameras and/or flashes) for capturing and storing fixed or moving images. Due to the portability of their host PEDs, however, such image capturing systems are often susceptible to damage. As many PEDs are costly, such damage is undesirable.

Embodiments of the present disclosure provide an accessory case for a PED that includes a camera protection system. In some embodiments, the accessory case may include selectively positionable protection covers integrated into the case. In certain embodiments, the protection covers may be articulated to a desired position along a hinge, rotationally, and/or along a slide track or channel. When the protection covers are in a closed position, external components of an image capturing system may be protected from external damage. When the protection covers are in an open position, the image capturing system may be used according to its normal functions.

Embodiments may be best understood by reference to the drawings. It will be readily understood that the components of the present disclosure, as generally described and illustrated in the drawings herein, could be arranged and designed in a wide variety of different configurations. Thus, the following more detailed description of the embodiments of the apparatus is not intended to limit the scope of the disclosure, but is merely representative of possible embodiments of the disclosure. In some cases, well-known structures, materials, or operations are not shown or described in detail.

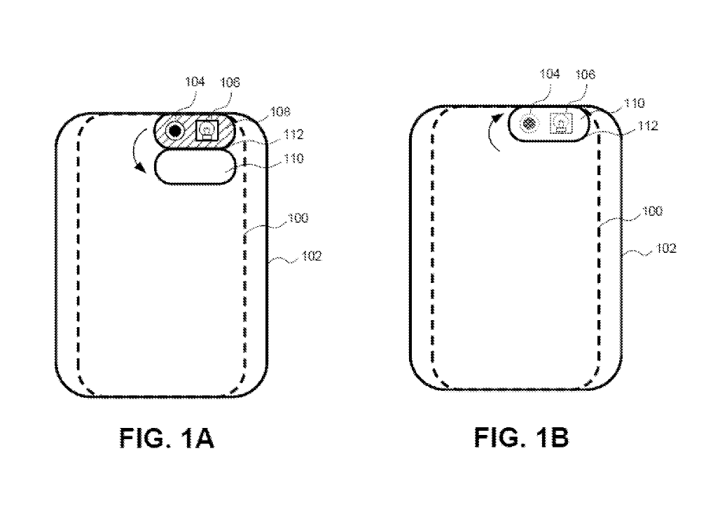

FIG. 1A illustrates a back view of an accessory 102, herein referenced as a holder, for a PED 100 that includes a hinged camera protection cover 110 in an open position consistent with embodiments of the present disclosure. The illustrated holder 102 may be referred to as a stand, case, sleeve, mount, and the like and, as used herein, does not necessarily imply an encasing or retaining functionality, although some embodiments of the holder 102 may have such functionalities. The PED 100 may be any portable electronic device including, for example, a notebook computer, an electronic book reader (e.g., the Amazon® Kindler“”), a smartphone (e.g., the Apple® iPhone™, the Motorola® Droid®, and the BlackBerry® Storm™), and/or a tablet computer (e.g., the Apple® iPad™, the HP® Slate, and the Samsung® Galaxy™ Tablet). In the illustrated embodiment, the PED 100 is an Apple® iPad™.

The holder 102 can be configured to receive a PED 100, and may further function to retain, carry, and protect the PED 100. The PED 100 can include on the and/or front or the back face of the PED 100 a display (not shown) that is viewable in either a portrait orientation or a landscape orientation, a user input (not shown), and a data input/output port (not shown). In some embodiments, the holder 102 may configured such that the display, user input, and data input/output port are accessible by a user of the PED 100 while the PED 100 is disposed in the holder 102. Further, in some embodiments, the holder 102 may include a protective screen disposed over the display.

In certain embodiments, the holder 102 is configured to grip or otherwise secure the PED 100. For example, the holder 102 may comprise a resilient material that can selectively expand so as to receive the PED 100 through a front opening and resiliently close about an outer edge of the PED 100. The holder 102 may also be configured to substantially cover the entirety of a back face of the PED 100. In some embodiments, the holder 102 may comprise a rubber or other elastomeric material (e.g., silicone) configured to provide a secure friction fit around the perimeter of the PED 100 to secure the holder 102 around the PED 100. The holder 102 may also comprise rigid materials (e.g., plastic, metal, and the like) and include a rigid frame. In some embodiments, the holder 102 may comprise releasable clips, straps, or other locking features that allow for the PED 100 to be selectively locked into the holder 102 and selectively released from the holder 102.

The PED 100 may include an integrated an image capturing system that may comprise a camera 104 and/or flash 106 system. The image capturing system may also include additional hardware and/or software components (not shown) internal to the PED 100 used to enable the functionality of the image capturing system. As shown in FIG. 1A, the camera 104 and/or flash 106 systems may be disposed on the back face of the PED 100. As discussed in more detail below, however, a PED 100 may also include one or more image capturing systems disposed on other faces of the PED 100 (e.g., a camera the front face and/or the front and back faces of the PED 100).

Consistent with embodiments disclosed herein, the holder 102 may comprise at least one selectively positionable protection cover 110 integrated into the holder 102. The protection cover 110 may be configured to be selectively articulated in a closed position to cover and protect a portion 108 of the back face of the PED 100 that the camera 104 and/or flash 106 are located on when the image capturing system is not in use. When a user of the PED 100 desires to use the image capturing system 104, 106, the user may selectively articulate the protection cover 110 to an open position, thereby exposing the portion 108 of the face of the PED 100 where the camera 104 and/or flash 106 are located.

In some embodiments, the protection cover 110 may be selectively articulated along a horizontal or lateral hinge 112 disposed on a side of the protection cover 110 and an opening of the holder 102 that exposes the portion 108 of the back face of the PED 100 that includes the camera 104 and/or flash 106. If the hinge 112 is horizontally disposed, as illustrated in FIG. 1., the protection cover 110 may open and close in an up and/or down direction. If the hinge 112 is laterally disposed, the protection cover 110 may open and or close in a left and/or right direction.

FIG. 1B illustrates a back view of the holder 102 where the protection cover 110 is in a closed position consistent with embodiments of the present disclosure. As shown, when articulated into a closed position along the hinge 112, the protection cover 110 may cover and protect the camera 104 and/or flash 106 of the PED's 100 image capturing system when the system is not in use. In certain embodiments, a knob, handle, grip, grasp and/or similar mechanical device may be disposed on the protection cover 110 and/or the holder 102 to aid in articulating the protection cover 110 between a closed and an open position. Further, when in a closed position, the protection cover 110 may be secured in place using a mechanical snap, a friction fit, a spring-loaded latch, and/or other similar mechanical means of securing the protection cover 110 in a closed position.

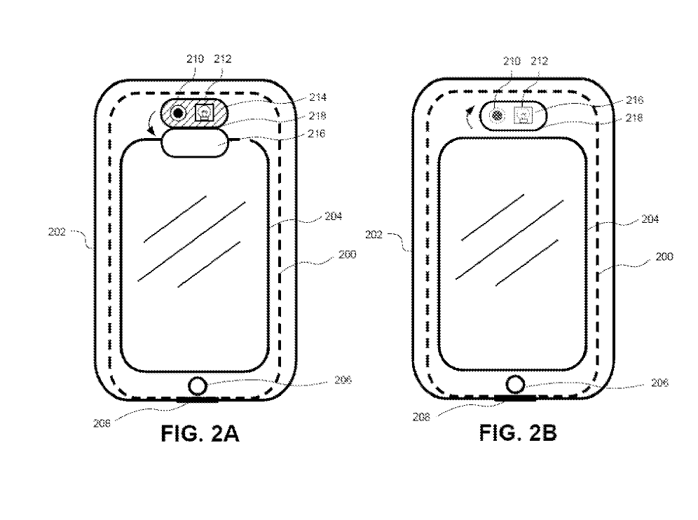

FIG. 2A illustrates a front view of a holder 202 for a PED 200 that includes a hinged camera protection cover 216 in an open position consistent with embodiments of the present disclosure. The illustrated holder 202 may be constructed similarly to the holder 102 discussed above in reference to FIGS. 1A and 1B. The PED 200 can include on the front and/or the back face of the PED 100 a display 204 that is viewable in either a portrait orientation or an landscape orientation, one or more user inputs 206, and a data input/output port 208. In some embodiments, the holder 102 may configured such that the display 204, user input 206, and data input/output port 208 are accessible by a user of the PED 200 while the PED 200 is disposed in the holder 202. Further, in some embodiments, the holder 202 may include a protective screen disposed over the display 204.

An image capturing system may be disposed on one or more faces of the PED 200 including, as illustrated in FIG. 2A, on the front face of the PED 200. The image capturing system may comprise a camera 210 and/or flash 212 system located on a portion 214 of the front face of the PED 200. The image capturing system may also include additional hardware and/or software components (not shown) internal to the PED 200 used to enable the functionality of the image capturing system.

Consistent with embodiments disclosed herein, the holder 202 may comprise at least one selectively positionable protection cover 216 integrated into the holder 202. The protection cover 216 may be configured to be selectively articulated in a closed position along hinge 218 to cover and protect the portion 214 of the front face of the PED 200 that the camera 210 and/or flash 212 are located on when the image capturing system is not in use. When a user of the PED 200 desires to use the image capturing system 210, 212, the user may selectively articulate the protection cover 216 to an open position along hinge 218, thereby exposing the portion 214 of the face of the PED 200 where the camera 210 and/or flash 212 are located. In some embodiments, the specific construction and operation of the protection cover 216 may be similar to that of the protection cover 110 discussed above in reference to the holder 102 illustrated in FIGS. 1A and AB.

FIG. 2B illustrates a front view of the holder 202 where the protection cover 216 is in a closed position consistent with embodiments of the present disclosure. As shown, when articulated into a closed position along the hinge 218, the protection cover 216 may cover and protect the camera 210 and/or flash 212 of the PED's image capturing system from damage when the system is not in use.

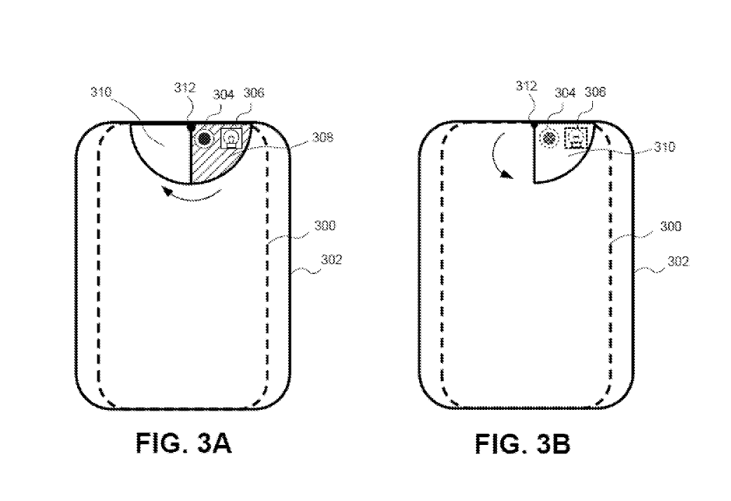

FIG. 3A illustrates a back view of a holder 302 for a PED 300 that includes a rotating camera protection cover 310 in an open position consistent with embodiments of the present disclosure. The illustrated holder 302 may be constructed similarly to the holder 102 discussed above in reference to FIGS. 1A-2B. An image capturing system may be disposed on one or more faces of the PED 300 including, as illustrated in FIG. 3A, on the back face of the PED 300. The image capturing system may comprise a camera 304 and/or flash 306 system located on a portion 308 of the back face of the PED 300. The image capturing system may also include additional hardware and/or software components (not shown) internal to the PED 300 used to enable the functionality of the image capturing system.

Consistent with embodiments disclosed herein, the holder 302 may comprise at least one selectively positionable protection cover 310 integrated into the holder 302. The protection cover 310 may be configured to be selectively articulated in a closed position to cover and protect the portion 308 of the back face of the PED 300 that the camera 304 and/or flash 306 are disposed upon when the image capturing system is not in use. When a user of the PED 300 desires to use the image capturing system 304, 306, the user may selectively articulate the protection cover 310 to an open position, thereby exposing the portion 308 of the face of the PED 300 where the camera 304 and/or flash 306 are located.

In some embodiments, the protection cover 310 may be selectively articulated in a rotational manner around a pivot 312. For example, in some embodiments, a point along an edge of the protection cover 310 may be coupled to a pivot 312 integrated in the protection cover 310 or the holder 302. When force is applied to the protection cover 310 around the pivot 312, the protection cover 310 may rotationally articulate. In certain embodiments, when articulated in an open position, the protection cover 310 may be located on the outside of the holder 302. In certain other embodiments, when articulated in an open position, the protection cover 310 may be located within a channel or area integrated inside the holder 302. In the embodiments illustrated in FIG. 3A, the protection cover 310 is located on the outside of the holder 310 when articulated in an open position.

FIG. 3B illustrates a back view of the holder 302 where the protection cover 310 is in a closed position consistent with embodiments of the present disclosure. As shown, when articulated into a closed position around the pivot 312, the protection cover 310 may cover and protect the camera 304 and/or flash 306 of the PED's 300 image capturing system when the system is not in use. In certain embodiments, a knob, handle, grip, grasp and/or similar mechanical device may be disposed on the protection cover 310 and/or the holder 302 to aid in rotationally articulating the protection cover 310 between a closed and an open position. Further, when in a closed position, the protection cover 310 may be secured in place using a mechanical snap, a friction fit, a spring-loaded latch, and/or other similar mechanical means of securing the protection cover 310 in a closed position.

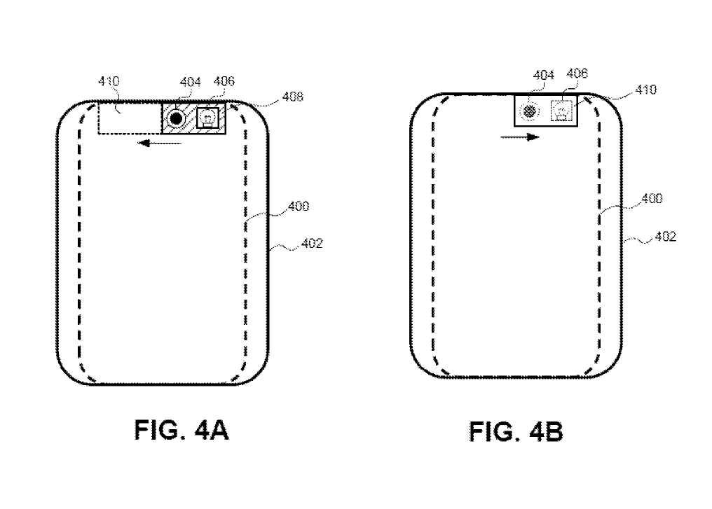

FIG. 4A illustrates a back view of a holder 402 for a PED 400 that includes a sliding camera protection cover 410 in an open position consistent with embodiments of the present disclosure. The illustrated holder 402 in may be constructed similarly to the holder 102 discussed above in reference to FIGS. 1A and 2B. An image capturing system may be disposed on one or more faces of the PED 400 including, as illustrated in FIG. 4A, on the back face of the PED 400. The image capturing system may comprise a camera 404 and/or flash 406 system located on a portion 408 of the back face of the PED 400. The image capturing system may also include additional hardware and/or software components (not shown) internal to the PED 400 used to enable the functionality of the image capturing system.

Consistent with embodiments disclosed herein, the holder 402 may comprise at least one selectively positionable protection cover 410 integrated into the holder 402. The protection cover 410 may be configured to be selectively articulated in a closed position to cover and protect a portion 408 of the back face of the PED 400 that the camera 404 and/or flash 406 are located on when the image capturing system is not in use. When a user of the PED 400 desires to use the image capturing system 404, 406, the user may selectively articulate the protection cover 410 to an open position, thereby exposing the portion 408 of the face of the PED 400 where the camera 404 and/or flash 406 are located.

In some embodiments, the protection cover 410 may be selectively articulated in a sliding manner along a track and/or channel integrated in the holder 402. For example, in some embodiments, a track and/or or channel configured to receive the protection cover 410 may be integrated in the holder 402 in either a horizontal configuration or a vertical configuration. In a horizontal configuration, as illustrated in FIG. 4A., the protection cover 310 may open and close by sliding along the track or channel in left and/or right direction. In a vertical configuration, the protection cover 310 may open and close by sliding along the track or channel in an up and/or down direction.

In certain embodiments, when articulated in an open position, the protection cover 410 may be located in a track and/or channel located on the outside of the holder 402. In certain other embodiments, when articulated in an open position, the protection cover 410 may be located within a track or channel integrated inside the holder 402. In the embodiments illustrated in FIG. 4A, the protection cover 410 is located in a channel integrated horizontally on the inside of the holder 410 when articulated in an open position.

FIG. 4B illustrates a back view of the holder 402 where the protection cover 410 is in a closed position consistent with embodiments of the present disclosure. As shown, when articulated into a closed position along the track and/or channel, the protection cover 410 may cover and protect the camera 404 and/or flash 406 of the PED's 400 image capturing system when the system is not in use. In certain embodiments, a knob, handle, grip, grasp and/or similar mechanical device may be disposed on the protection cover 410 and/or the holder 402 to aid in sliding the protection cover 410 between a closed and an open position. Further, when in a closed position, the protection cover 410 may be secured in place using a mechanical snap, a friction fit, a spring-loaded latch, and/or other similar mechanical means of securing the protection cover 410 in a closed position.

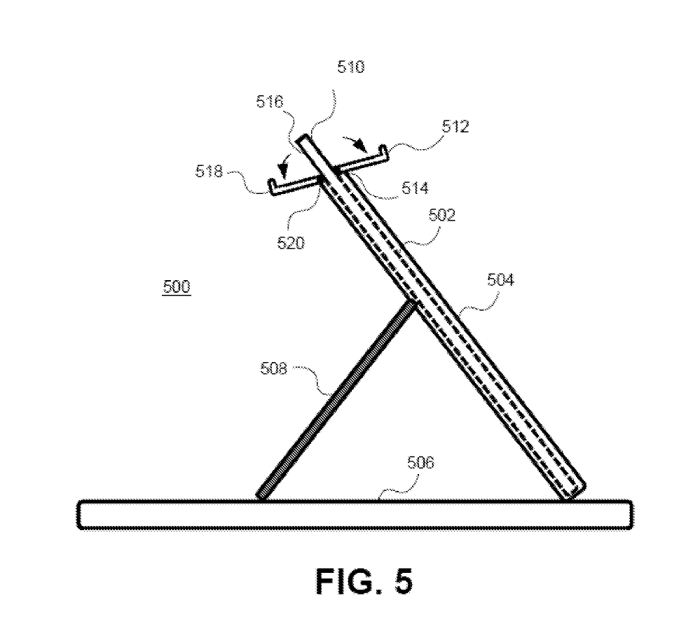

FIG. 5 illustrates a side elevation view of an embodiment of a stand case 500 for a PED 502 that includes hinged camera protection covers 512, 518 in open positions consistent with embodiments of the present disclosure. The stand case 500 may include a flexible and/or rigid holder 504 which, in some embodiments, may be similar to the holder 102 described in reference to FIGS. 1A and 1B. The holder 504 may be configured to receive and to secure the PED 502. Further, the holder 504 can be pivotally connected to a stand base 506 which may be constructed of rigid and/or non-rigid materials, enabling folding of the holder 504 against the stand base 506.

A support rest 508 constructed of rigid and/or non-rigid materials may be pivotally connected to either the stand base 506 or the holder 504, and may be used to adjust a viewing angle of the PED 502 by varying the angle between the holder 504 and the stand base 506. In some embodiments, one end of the support rest 508 may be pivotally connected to either the stand base 506 or the holder 504, and the other end of the support rest 508 may be received in a sliding track (not shown) integrated into either the stand base 506 or the holder 504, enabling a user to adjust the viewing angle of PED 502. Further, in other embodiments, one end of the support rest 508 may be pivotally connected to either the stand base 506 or the holder 504, and the other end of the support rest 508 may be selectively attached (e.g., via Velcro, clasps, snaps, or the like) at varying positions to either the stand base 506 or the holder 504, enabling a user to adjust the viewing angle of PED 502

An image capturing system may be disposed on one or more faces of the PED 502 including, as illustrated in FIG. 5, on both the front and back faces of the PED 502. The image capturing systems may comprise a camera and/or flash system located on a portion 510 of the front face of the PED 502 and a portion 516 of the back face of the PED 502. The image capturing systems may also include additional hardware and/or software components (not shown) internal to the PED 502 used to enable the functionality of the image capturing systems.

Consistent with embodiments disclosed herein, the holder 504 may comprise selectively positionable protection covers 512, 518 integrated into the holder 504 configured to protect the image capturing system of the PED 502. In some embodiments, the protection covers 512, 518 may be configured to be selectively articulated along hinges 514, 520 to cover and protect the portions 510, 516 of the PED 502 that the image capturing systems are located on when the image capturing systems are not in use. When a user of the PED 502 desires to use the image capturing systems, the user may selectively articulate the protection covers 512, 518 to open positions along the hinges 512, 518, thereby exposing the portions 510, 516 of the PED 502 where the imaging capturing systems are located.

In some embodiments, the specific construction and operation of the protection covers 512, 518 may be similar to that of the protection cover 110 discussed above in reference to the holder 102 illustrated in FIGS. 1A and AB. Accordingly, as illustrated in FIG. 5, a hinged articulation system may be used. Other articulation systems, however, may also be utilized to articulate the protection covers 512, 518 of the stand case 500. For example, a pivotal rotation system, as illustrated in FIGS. 3A and 3B, a sliding system, as illustrated in FIGS. 4A and 4B, or any other similar protection cover articulation systems may be utilized.

It will be understood by those having skill in the art that changes may be made to the details of the above-described embodiments without departing from the underlying principles presented herein. For example, the selectively positionable protection cover systems disclosed herein may be integrated into a stand, a mount, or any other type of accessory configured to receive a PED. In addition, any suitable combination of various embodiments, or the features thereof, is contemplated.

Any methods disclosed herein comprise one or more steps or actions for performing the described method. The method steps and/or actions may be interchanged with one another. In other words, unless a specific order of steps or actions is required for proper operation of the embodiment, the order and/or use of specific steps and/or actions may be modified.

Throughout this specification, any reference to “one embodiment,” “an embodiment,” or “the embodiment” means that a particular feature, structure, or characteristic described in connection with that embodiment is included in at least one embodiment. Thus, the quoted phrases, or variations thereof, as recited throughout this specification are not necessarily all referring to the same embodiment. Similarly, it should be appreciated that in the above description of embodiments, various features are sometimes grouped together in a single embodiment, figure, or description thereof for the purpose of streamlining the disclosure. This method of disclosure, however, is not to be interpreted as reflecting an intention that any claim require more features than those expressly recited in that claim. Rather, inventive aspects lie in a combination of fewer than all features of any single foregoing disclosed embodiment. It will be apparent to those having skill in the art that changes may be made to the details of the above-described embodiments without departing from the underlying principles set forth herein.

What is claimed is:

1. A case for a portable electronic device including an integrated image capturing system comprising:
a holder configured to secure the portable electronic device; and
a selectively positionable protection cover integrated into the holder configured to protect the integrated image capturing system.

2. The case of claim 1, wherein the image capturing system comprises a camera system.

3. The case of claim 1, wherein the image capturing system comprises a flash system.

4. The case of claim 1, wherein the protection cover is selectively positionable using an articulating hinge mechanism.

5. The case of claim 1, wherein the protection cover is selectively positionable using a sliding mechanism.

6. The case of claim 1, wherein the protection cover is selectively positionable able using an articulating rotational mechanism.

7. The case of claim 1, wherein the protection cover is selectively positionable between a closed position and an open position.

8. The case of claim 7, wherein the protection cover is configured to protect the integrated image capturing system when positioned in the closed position

9. The case of claim 7, wherein the protection cover is configured to allow use of the image capturing system when positioned in an open position.

10. The case of claim 7, wherein the protection cover is configured to be secured in the closed position using a mechanical snap mechanism.

11. The case of claim 7, wherein the protection cover is configured to be secured in the closed position using a friction fit mechanism.

12. The case of claim 7, wherein the protection cover is configured to be secured in the closed position using a spring-loaded latch mechanism.

13. The case of claim 1, wherein the protection cover comprises a grasp mechanism configured to aid a user in selectively positioning the protection cover.

14. The case of claim 1, wherein the holder is configured to protect a front surface of the portable electronic device.

15. The case of claim 1, wherein the holder is configured to protect a back surface of the portable electronic device.

16. The case of claim 1, wherein the holder is configured to secure the portable electronic device using a compression fit.

17. The case of claim 1, wherein the holder comprises a resilient material configured to selectively expand and receive the portable electronic device.

18. The case of claim 1, wherein the case further comprises a second selectively positionable protection cover integrated into the holder configured to protect a second image capturing system of the portable electronic device.

19. A stand case for a portable electronic device including an integrated image capturing system comprising:
a holder configured to secure the portable electronic device;
a base pivotally coupled to the holder;
a support rest configured to variable secure the holder in an upright position relative to the base; and
a selectively positionable protection cover integrated into the holder configured to protect the integrated image capturing system.
